(19) United States
(12) Patent Application Publication
(10) Pub. No.: US 2026/0210789 A1
(43) Pub. Date: Jul. 23, 2026

(54) SYSTEM AND METHOD FOR DETECTING LEAK IN SEMICONDUCTOR EQUIPMENT

(71) Applicant: SAMSUNG ELECTRONICS CO., LTD., Suwon-si (KR)

(72) Inventors: Chongyong NAM, Suwon-si (KR); Hyuncheol JEONG, Suwon-si (KR); Yujin HAN, Suwon-si (KR); Daehyun LEE, Suwon-si (KR); Choong KIM, Suwon-si (KR); Seongkyun OH, Suwon-si (KR); Eunsu LEE, Suwon-si (KR)

(73) Assignee: SAMSUNG ELECTRONICS CO., LTD., Suwon-si (KR)

(21) Appl. No.: 19/268,491

(22) Filed: Jul. 14, 2025

(30) Foreign Application Priority Data
Jan. 21, 2025 (KR) 10-2025-0009116

(51) Int. Cl. G01M 3/02; H01L 21/67

(52) U.S. Cl. CPC G01M 3/02; H10P 72/0402

(57) ABSTRACT

A system may include: a process chamber; a vacuum pump; a vacuum pipe; a leak detection chamber including a leak detection sensor that detects whether a leakage occurs in the system; a sensor protection valve that controls whether air inside the vacuum pipe contacts the leak detection sensor; and a controller that controls operations of the vacuum pump and the sensor protection valve according to a process progress state of the process chamber, wherein the controller operates the vacuum pump before or after execution of a process by the process chamber, and controls the sensor protection valve to open so that the leak detection chamber fluidly communicates with the vacuum pipe, wherein the leak detection sensor acquires composition data of air inside the vacuum pipe, and wherein the controller determines whether the system is leaking based on the composition data.

### CROSS-REFERENCE TO RELATED APPLICATION

This application claims priority to Korean Patent Application No. 10-2025-0009116,filed in the Korean Intellectual Property Office on Jan. 21, 2025, the disclosure of which is herein incorporated by reference in its entirety.

### BACKGROUND

### 1. Field

Some embodiments of the present disclosure relate to a leak detection system and method for semiconductor equipment.

### 2. Brief Description of Background Art

With advancements in semiconductor manufacturing technology, the degree of integration of semiconductor products is increasing. Additionally, in order to maintain the reliability and stability of semiconductor manufacturing processes, a high-vacuum environment in semiconductor manufacturing equipment is required. However, if leakage occurs in semiconductor manufacturing equipment, the required high-vacuum state may not be maintained, or even if the high-vacuum state is maintained, changes in the air composition inside the semiconductor manufacturing equipment may cause degradation in the quality of the semiconductor products.

Various technologies may be used to detect leaks in order to maintain the high-vacuum state or the air composition of semiconductor manufacturing equipment. For example, a pressure sensor may be used to detect pressure changes resulting from leakage in the semiconductor manufacturing equipment. However, when the pressure sensor is in fluid communication with a vacuum pump, there are limitations in detecting pressure changes caused by a minute inflow of gas into the equipment, and the range within which leakage may be detected is limited. In another example, a helium leak detection method may be used. However, this method may only be utilized when the equipment is in an idle state, and the process of detecting a leak requires a worker to directly inspect the equipment area, which is cumbersome.

### SUMMARY

According to an embodiment of the present disclosure, a leak detection system and method for semiconductor equipment may be provided that may rapidly and precisely detect minute leaks occurring in the semiconductor equipment regardless of the placement position of sensors, protect the leak detection sensor, and maintain the stability of the equipment.

However, technical problems solved by embodiments of the present disclosure are not limited to the aforementioned problems, and additional problems not mentioned that are solved by embodiments of the present disclosure may be clearly understood by those skilled in the art from the following description of the present disclosure.

According to some embodiments of the present disclosure, a system may be provided and include: a process chamber; a vacuum pump configured to maintain the process chamber in a vacuum state; a vacuum pipe connecting an interior of the process chamber and the vacuum pump; a leak detection chamber connected to the vacuum pipe, the leak detection chamber including a leak detection sensor configured to detect whether a leakage occurs in the system; a sensor protection valve between the vacuum pipe and the leak detection chamber, the sensor protection valve configured to control whether air inside the vacuum pipe contacts the leak detection sensor; and a controller including at least one processor, the controller configured to control operations of the vacuum pump and the sensor protection valve according to a process progress state of the process chamber, wherein the controller is further configured to operate the vacuum pump before or after execution of a process by the process chamber, and control the sensor protection valve to open so that the leak detection chamber fluidly communicates with the vacuum pipe, wherein, in a state where the leak detection chamber and the process chamber are in fluid communication, the leak detection sensor is configured to acquire composition data of air inside the vacuum pipe, and wherein the controller is further configured to determine whether the system is leaking based on the composition data.

According to some embodiments of the present disclosure, a controller may be provided and include at least one processor configured to: control a sensor protection valve, that is between a vacuum pipe and a leak detection chamber, to open so that the leak detection chamber fluidly communicates with the vacuum pipe, the leak detection chamber including a leak detection sensor; control a gate valve on the vacuum pipe to open so that a process chamber and a vacuum pump fluidly communicate with each other; determine, based on composition data of air inside at least one from among the process chamber and the vacuum pipe acquired by the leak detection sensor, whether semiconductor equipment is leaking, the semiconductor equipment including the process chamber and the vacuum pipe; control the sensor protection valve to close so as to block fluid communication between the vacuum pipe and the leak detection chamber; and control a mass flow controller (MFC) on a gas pipe so that process gas is supplied to the process chamber by a gas supply chamber, the gas pipe configured to place the gas supply chamber in fluid communication with the process chamber.

According to some embodiments of the present disclosure, a system may be provided and include: a process chamber; a vacuum pump configured to maintain the process chamber in a vacuum state; a vacuum pipe connecting an interior of the process chamber and the vacuum pump; a gate valve on the vacuum pipe, the gate valve configured to control whether the process chamber and the vacuum pump fluidly communicate with each other; a leak detection chamber connected to the vacuum pipe, the leak detection chamber including a leak detection sensor configured to detect whether a leakage occurs in the system; a sensor protection valve between the vacuum pipe and the leak detection chamber, the sensor protection valve configured to control whether air inside the vacuum pipe contacts the leak detection sensor; a purge chamber connected to the leak detection chamber, the purge chamber including a purge gas supplier configured to supply a purge gas into the leak detection chamber; a purge pipe; a purge valve on the purge pipe, the purge valve configured to place the leak detection chamber and the purge chamber in fluid communication and control an amount of the purge gas supplied into the leak detection chamber; and a controller including at least one processor, the controller configured to control an operation of at least one from among the gate valve, the sensor protection valve, the purge valve, the vacuum pump, the leak detection sensor, and the purge gas supplier according to a process progress state of the process chamber, wherein the controller is further configured to operate the vacuum pump before or after execution of a process by the process chamber, and open the sensor protection valve so that the leak detection chamber fluidly communicates with the process chamber, wherein the controller is further configured to in a state where the leak detection chamber and the process chamber are in fluid communication, control the leak detection sensor to acquire composition data of air inside the vacuum pipe, and wherein the controller is further configured to determine whether the system is leaking based on the composition data.

According to some embodiments of the present disclosure, a method performed by a controller, including at least one processor, may be provided and include: opening a sensor protection valve that is between a vacuum pipe and a leak detection chamber so that the leak detection chamber fluidly communicates with the vacuum pipe, the leak detection chamber including a leak detection sensor; opening a gate valve on the vacuum pipe so that a process chamber and a vacuum pump fluidly communicate with each other; acquiring, by the leak detection sensor, composition data of air inside at least one from among the process chamber and the vacuum pipe; determining, based on the composition data, whether semiconductor equipment is leaking, the semiconductor equipment including the process chamber and the vacuum pipe; closing the sensor protection valve so as to block fluid communication between the vacuum pipe and the leak detection chamber; and controlling a mass flow controller (MFC) on a gas pipe so that process gas is supplied to the process chamber by a gas supply chamber, the gas pipe configured to place the gas supply chamber in fluid communication with the process chamber.

According to some embodiments of the present disclosure, it is possible to provide a leak detection system capable of detecting minute leaks inside semiconductor equipment regardless of the sensor placement position. This allows the high-vacuum state in semiconductor manufacturing processes to be maintained or the air composition inside the chamber under the high-vacuum state to be maintained, thereby improving process quality.

According to some embodiments of the present disclosure, a sensor protection valve may be installed between a leak detection chamber including a leak detection sensor and a vacuum pipe to protect the leak detection sensor from physical or chemical damage caused by process gas or external air components. This may minimize the influence of the external environment on the leak detection sensor and allow the leak detection sensor to operate in a stable environment.

According to some embodiments of the present disclosure, the leak detection sensor may be protected using purge gas, and physical or chemical damage caused by process gas or external air components may be prevented. This may extend the lifespan of the leak detection sensor and ensure the reliability of detection data.

### BRIEF DESCRIPTION OF DRAWINGS

FIG. 1 illustrates a leak detection system of semiconductor equipment according to some embodiments of the present disclosure in a schematic manner.

FIG. 2 illustrates a leak detection system of semiconductor equipment according to some embodiments of the present disclosure.

FIG. 3 illustrates a leak detection system of semiconductor equipment according to some embodiments of the present disclosure.

FIG. 4 illustrates a leak detection system of semiconductor equipment according to some embodiments of the present disclosure.

FIG. 5 is a flowchart illustrating a leak detection method of semiconductor equipment according to some embodiments of the present disclosure.

FIGS. 6-9 illustrate the leak detection method of the semiconductor equipment of FIG. 5 according to some embodiments of the present disclosure.

FIG. 10 is a flowchart illustrating a leak detection method of semiconductor equipment according to some embodiments of the present disclosure.

FIG. 11 illustrates the leak detection method of the semiconductor equipment of FIG. 10 according to some embodiments of the present disclosure.

FIG. 12 is a flowchart illustrating a leak detection method of semiconductor equipment according to some embodiments of the present disclosure.

FIG. 13 illustrates the leak detection method of the semiconductor equipment of FIG. 12 according to some embodiments of the present disclosure.

FIG. 14 is a flowchart illustrating a leak detection method of semiconductor equipment according to some embodiments of the present disclosure.

FIG. 15 illustrates the leak detection method of the semiconductor equipment of FIG. 14 according to some embodiments of the present disclosure.

FIG. 16 is a block diagram illustrating a configuration of a computing device implementing a controller according to some embodiments of the present disclosure.

### DETAILED DESCRIPTION

Hereinafter, with reference to the drawings, a leak detection system and method of semiconductor equipment according to some non-limiting example embodiments of the present disclosure will be described in detail.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

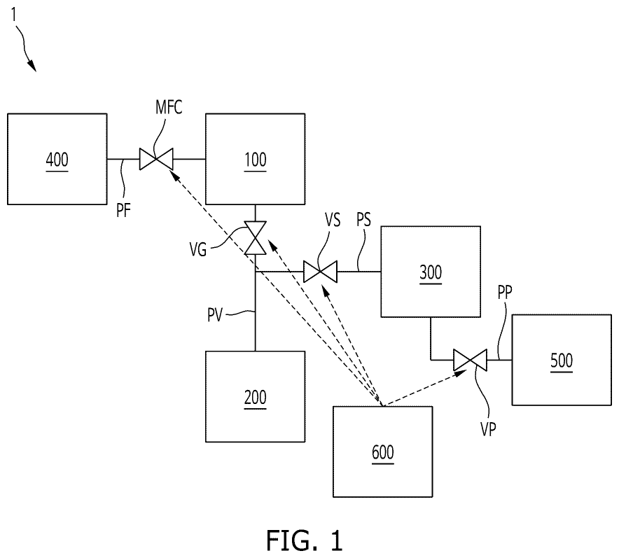

FIG. 1 illustrates a leak detection system of semiconductor equipment according to some embodiments of the present disclosure in a schematic manner.

Referring to FIG. 1, the leak detection system 1 of the semiconductor equipment may include a process chamber 100, a vacuum pump 200, a leak detection chamber 300, a vacuum pipe PV, a sensor pipe PS, a sensor protection valve VS, and a controller 600.

The process chamber 100 may provide a processing space for a substrate. For example, a photolithography process, an etching process, a deposition process, and/or a cleaning process may be performed on the substrate in the process chamber 100. The process chamber 100 may receive process gas from a gas supply chamber 400 and perform a semiconductor manufacturing process on the substrate. Although the process chamber 100 may form a part of an exposure apparatus, an etching apparatus, a deposition apparatus, or a cleaning apparatus, embodiments of the present disclosure are not limited thereto. The term “substrate” used herein may mean a semiconductor substrate such as a silicon (Si) wafer, but is not limited thereto.

The internal environment of the process chamber 100 may be controlled so as to satisfy various conditions to maintain characteristics of semiconductor manufacturing processes that require high precision. The process chamber 100 may include a sealed structure to maintain a vacuum atmosphere or airtightness. The process chamber 100 may also include at least one port so that the inflow of gas from the outside and the outflow of gas from the inside may be controlled.

The vacuum pump 200 may be configured to maintain the process chamber 100 in a vacuum state. The vacuum pump 200 may discharge air from the interior of the process chamber 100 to the outside to lower the internal pressure and form a high-vacuum environment, or may maintain the internal pressure of the process chamber 100 at a predetermined pressure. The vacuum pump 200 may be configured to remove residual gas that may occur inside the process chamber 100.

The vacuum pipe PV may be disposed so as to be connected between one side of the process chamber 100 and the vacuum pump 200. The vacuum pipe PV may be configured to place the interior of the process chamber 100 and the vacuum pump 200 in fluid communication. The vacuum pipe PV may be formed of a sealed material to prevent equipment leakage. The vacuum pipe PV may include a valve and/or a filter to optimize internal fluid flow.

The leak detection chamber 300 may be connected to at least a portion of the vacuum pipe PV. The leak detection chamber 300 may be connected to the interior of the vacuum pipe PV through the sensor pipe PS, which fluidly communicates with the vacuum pipe PV.

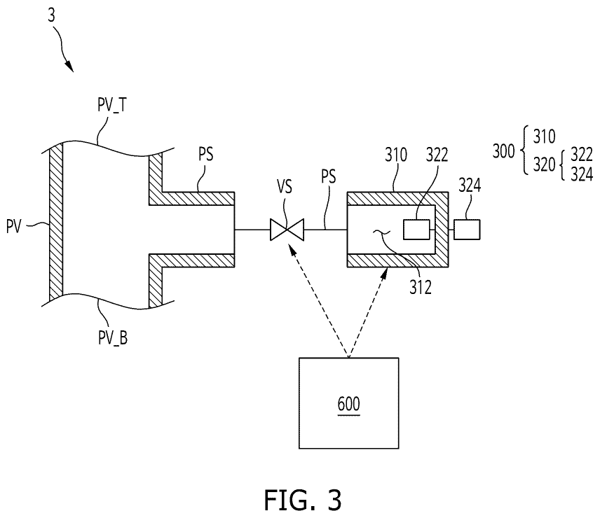

The leak detection chamber 300 may include a leak detection sensor configured to detect whether leakage occurs in the semiconductor equipment including the process chamber 100 and the vacuum pipe PV. When the leak detection chamber 300 and the semiconductor equipment are in fluid communication through the sensor pipe PS, the leak detection sensor may acquire composition data of the air inside the vacuum pipe PV. The leak detection sensor (or the controller 600) may be configured to determine whether leakage has occurred in the semiconductor equipment based on the acquired composition data. Hereinafter, details of the configuration and function of the leak detection sensor will be described below with reference to FIG. 3.

The sensor pipe PS may include the sensor protection valve VS. The sensor protection valve VS may be installed on the sensor pipe PS. The sensor protection valve VS may be disposed between the vacuum pipe PV and the leak detection chamber 300. The sensor protection valve VS may be configured to control whether the internal air of the vacuum pipe PV is brought into contact with the leak detection sensor.

Referring to FIG. 1, the leak detection system 1 of the semiconductor equipment may further include a gate valve VG installed on the vacuum pipe PV and configured to control whether the process chamber 100 and the vacuum pump 200 communicate with each other. The gate valve VG may maintain airtightness between the process chamber 100 and the vacuum pump 200 and, as required, isolate the vacuum state of the process chamber 100 or place the interior of the process chamber 100 in fluid communication with the vacuum pump 200. For example, when maintenance work is performed on the vacuum pipe PV, the gate valve VG may be closed, and the interior of the process chamber 100 may be pressurized so that the interior of the process chamber 100 is set to atmospheric pressure without being affected by a pressure change caused by the vacuum pump 200. Further, when the gate valve VG is opened, the process chamber 100 may be connected to the vacuum pump 200 through the vacuum pipe PV. While the gate valve VG is open, if the vacuum pump 200 operates, the vacuum pump 200 may discharge residual gas inside the process chamber 100 to the outside or reduce the pressure of the process chamber 100.

The leak detection system 1 of the semiconductor equipment may further include a pressure sensor connected to the vacuum pipe PV at the upstream side of the gate valve VG. In this configuration, the leak detection sensor included in the leak detection chamber 300 may detect leakage of the semiconductor equipment together with the pressure sensor. For example, leakage in the vacuum pipe PV or the process chamber 100 on the upstream side of the gate valve VG may be detected by the pressure sensor. On the other hand, not only leakage at the upstream side of the gate valve VG but also leakage in the vacuum pipe PV downstream of the gate valve VG or in the vacuum pump 200 may be detected by the leak detection sensor of the leak detection chamber 300.

Referring to FIG. 1, the sensor pipe PS may be connected the vacuum pipe PV downstream of the gate valve VG (or on the exhaust side). The leak detection sensor included in the leak detection chamber 300 may be disposed so as to be connected to the vacuum pipe PV between the gate valve VG and the vacuum pump 200, and configured to detect leakage of the semiconductor equipment.

Referring to FIG. 1, the leak detection system 1 of the semiconductor equipment may further include the gas supply chamber 400 (or a gas supply device), the process chamber 100, a process gas pipe PF configured to place the process chamber 100 and the gas supply chamber 400 in fluid communication, and a mass flow controller MFC installed on the process gas pipe PF and configured to control the flow rate of process gas supplied into the process chamber 100.

The gas supply chamber 400 may store or prepare process gas to be supplied to the process chamber 100. The process gas pipe PF may be configured to connect the gas supply chamber 400 and the process chamber 100, and may supply process gas into the process chamber 100.

The gas supply chamber 400 may supply process gas or purge gas into the interior of the process chamber 100. The purge gas may be used to maintain the interior of the process chamber 100 clean after a process is completed or to remove residual process gas in preparation for a subsequent process. An inert purge gas (e.g., nitrogen gas) may serve to stabilize the internal environment of the process chamber 100 and prevent unnecessary chemical reactions or contamination.

The mass flow controller MFC may be installed on the process gas pipe PF and be configured to control the flow of process gas. By controlling the flow rate and amount of process gas supplied to the process chamber 100, the MFC may provide a gas environment suitable for the process conditions within the process chamber 100.

Referring to FIG. 1, the leak detection system 1 of the semiconductor equipment may further include the leak detection chamber 300, a purge chamber 500, a purge pipe PP configured to place the leak detection chamber 300 and the purge chamber 500 in fluid communication, and a purge valve VP installed on the purge pipe PP and configured to control an amount of purge gas supplied into the leak detection chamber 300.

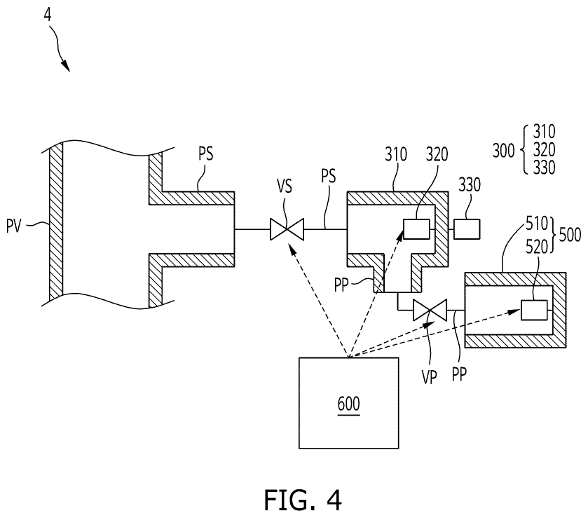

The purge chamber 500 may be disposed on one side of the leak detection chamber 300. The purge chamber 500 may be in fluid communication with the interior of the leak detection chamber 300 through the purge pipe PP and the purge valve VP. The purge chamber 500 may include a purge device configured to supply purge gas into the leak detection chamber 300. Through the supplied purge gas, purging may be performed inside the leak detection chamber 300. Details of the configuration and function of the purge chamber 500 will be described below with reference to FIG. 4.

Referring to FIG. 1, the controller 600 may include at least one processor and may be configured to control operations and/or states of at least one component included in the leak detection system 1 of the semiconductor equipment according to the process progress state of the process chamber 100. For example, the controller 600 may be configured to control operations of one or more (e.g., some or all) from among the sensor protection valve VS, the gate valve VG, the MFC, and the purge valve VP. Also, the controller 600 may be configured to control operations of the vacuum pump 200, the leak detection sensor, the purge device, and the gas supply device. The controller 600 may control an operation one or more (e.g., some or all) from among a plurality of valves according to various process operations, including before or after stabilization of the leak detection sensor, before or after a vacuuming operation of the process chamber 100, or before or after a main process operation inside the process chamber 100. The controller 600 may manage operations of the semiconductor equipment (including the leak detection system 1 of the semiconductor equipment) by controlling the operational state of the vacuum pump 200, analyzing signals from the leak detection sensor, and controlling operations of the purge device and the gas supply device.

In FIG. 1, a single controller is shown controlling operations and/or states of at least one component of the leak detection system 1 of the semiconductor equipment, but the number of controllers is not limited thereto. For example, the controller 600 may include a plurality of controllers, each of which may independently or cooperatively control operations of corresponding components. Further, the controller 600 may be connected to the leak detection system 1 of the semiconductor equipment through a wired or wireless network and may control operations and/or states of at least one component of the leak detection system 1.

The controller 600 may control the MFC installed on the process gas pipe PF so that process gas may be supplied into the process chamber 100 through the process gas pipe PM. Through this, the controller 600 may adjust the flow rate and pressure of the process gas supplied into the process chamber 100 according to process requirements.

The controller 600 may control the gate valve VG installed on the vacuum pipe PV and configured to control whether the process chamber 100 and the vacuum pump 200 are in fluid communication. Before a process is executed in the process chamber 100, the controller 600 may open the gate valve VG in order to maintain the vacuum degree of the process chamber 100 until execution of the process begins. On the other hand, before or after a process is executed in the process chamber 100, the controller 600 may close the gate valve VG so as to cut off fluid communication between the process chamber 100 and the vacuum pump 200, thereby detecting a pressure increase trend inside the process chamber 100 to determine whether leakage occurs. To this end, a pressure sensor may be further installed on the vacuum pipe PV at the upstream side of the gate valve VG. However, in such a case, leakage at the downstream side of the gate valve VG on the vacuum pipe PV cannot be detected by the pressure sensor. Also, even if the pressure sensor is disposed in the vacuum pipe PV downstream of the gate valve VG, it may be difficult for that pressure sensor to detect an increase in pressure because it is in fluid communication with the vacuum pump 200. Meanwhile, the leak detection sensor installed in the leak detection chamber 300 (e.g., an oxygen sensor) may detect a leak regardless of whether it is installed downstream of the gate valve VG on the vacuum pipe PV or at another position inside the semiconductor equipment. This will be described in more detail below.

Before a process is executed, the controller 600 may control the sensor protection valve VS to open so that the leak detection chamber 300 may be in fluid communication with the vacuum pipe PV. In this state, the leak detection sensor may be configured to acquire composition data of the air inside the vacuum pipe PV, and if the gate valve VG is open, the process chamber 100 may be in fluid communication with the vacuum pipe PV, so that the leak detection sensor may acquire composition data of the air inside the process chamber 100. The controller 600 may analyze the acquired data to determine whether the semiconductor equipment is leaking.

During the execution of a process, the controller 600 may control the sensor protection valve VS to close so that the leak detection sensor 320 is not exposed to process gas. By closing the sensor protection valve VS, the controller 600 may prevent chemically reactive or high-temperature process gas from entering the leak detection chamber 300 through the sensor pipe PS and may protect the leak detection sensor 320 from damage.

Before or after execution of a process, the controller 600 may ensure that during the operation of vacuum pump 200, the sensor protection valve VS is opened, thereby enabling the leak detection sensor to establish fluid communication with the vacuum pipe PV. In the state where the leak detection chamber 300 and the semiconductor equipment are in fluid communication, the controller 600 may manage the leak detection sensor to acquire the air composition data inside vacuum pipe PV; if the gate valve VG is open, the system is configured such that the process chamber 100 and the vacuum pipe PV are in fluid communication, enabling acquisition of the air composition data within the process chamber 100. Additionally, the controller 600 can determine the possibility of leakage in the semiconductor equipment based on the acquired composition data.

According to the above-described configuration, the controller 600 may monitor the process progress state in real time and coordinate the operations of valves installed in the process chamber 100, the leak detection chamber 300, and related pipes to determine whether the semiconductor equipment is leaking, thereby ensuring equipment safety and reliability.

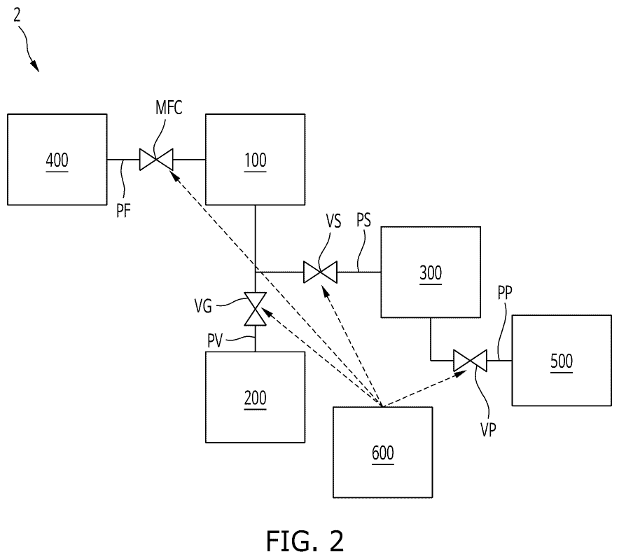

FIG. 2 illustrates a leak detection system 2 of semiconductor equipment according to some embodiments of the present disclosure.

Referring to FIG. 2, the leak detection system 2 of the semiconductor equipment may include the process chamber 100, the vacuum pump 200, the leak detection chamber 300, the gas supply chamber 400, the purge chamber 500, the controller 600, the vacuum pipe PV, the sensor pipe PS, the gas pipe PF, the purge pipe PP, the gate valve VG, the sensor protection valve VS, the mass flow controller MFC, the purge valve VP, and so forth. Hereinafter, overlapping content with FIG. 1 may not be repeated or may be briefly described.

The sensor pipe PS may be connected to the vacuum pipe PV at the upstream side of the gate valve VG. The leak detection sensor included in the leak detection chamber 300 may be disposed so as to be connected the vacuum pipe PV between the gate valve VG and the process chamber 100, and be configured to detect leakage of the semiconductor equipment.

The leak detection system 2 of the semiconductor equipment may further include a pressure sensor connected to the vacuum pipe PV at the upstream side of the gate valve VG. As in FIG. 1, the leak detection sensor included in the leak detection chamber 300 may be configured to detect leakage of the semiconductor equipment together with the pressure sensor.

The controller 600 may control the gate valve VG installed on the vacuum pipe PV and configured to control whether the process chamber 100 and the vacuum pump 200 are in fluid communication. Before a process is executed in the process chamber 100, the controller 600 may open the gate valve VG so as to maintain a vacuum state inside the process chamber 100 by keeping fluid communication between the process chamber 100 and the vacuum pump 200. Also, while the gate valve VG is open and a process is performed in the process chamber 100, by the operation of the vacuum pump 200, byproducts or process gas generated during the process may be discharged to the outside.

Before a process is executed, the controller 600 may control the sensor protection valve VS to open so that the leak detection chamber 300 and the vacuum pipe PV are in fluid communication. In this state, the leak detection sensor may be configured to acquire composition data of the air inside the vacuum pipe PV. The controller 600 may analyze the acquired data to determine whether the semiconductor equipment is leaking.

During execution of a process in the process chamber 100, the controller 600 may control the sensor protection valve VS to close so that the leak detection sensor 320 is not exposed to the process gas. By closing the sensor protection valve VS, the controller 600 may prevent a chemically reactive or high-temperature process gas from flowing into the leak detection chamber 300 through the sensor pipe PS and may protect the leak detection sensor 320 from damage.

The controller 600, before or after the execution of a process, may, while operating the vacuum pump 200, control the sensor protection valve VS to open so that the leak detection sensor is in fluid communication with the vacuum pipe PV. In a state where the leak detection chamber 300 and the semiconductor equipment are in fluid communication, the leak detection sensor may acquire composition data of the air inside the vacuum pipe PV. Furthermore, the controller 600 may determine whether leakage occurs in the semiconductor equipment based on the acquired composition data.

According to the configurations illustrated in FIGS. 1 and 2, the leak detection sensor may detect minute leaks inside the semiconductor equipment regardless of the placement position on the vacuum pipe PV. Moreover, by responding to leaks detected by the leak detection sensor inside the semiconductor equipment, various high-vacuum conditions required in the semiconductor manufacturing process may be stably satisfied, and process quality may be improved.

FIG. 3 illustrates a leak detection system of semiconductor equipment according to some embodiments of the present disclosure.

Referring to FIG. 3, the leak detection system 3 of the semiconductor equipment may include the vacuum pipe PV, a sensor pipe PS connected to the vacuum pipe PV, a leak detection chamber 300 connected to the interior of the vacuum pipe PV through the sensor pipe PS, a sensor protection valve VS installed on the sensor pipe PS, and a controller 600 configured to control opening and closing of the sensor protection valve VS. The sensor pipe PS may be connected to the vacuum pipe PV between a process chamber-side vacuum pipe portion PV_T and a vacuum pump-side vacuum pipe portion PV_B. Hereinafter, overlapping content with FIGS. 1 and 2 may not be repeated or may be briefly described.

The leak detection chamber 300 may include a sidewall portion 310 providing an accommodation space 312 for a leak detection sensor 320, and the leak detection sensor 320. Here, the leak detection sensor 320 may include an inner portion 322 of the leak detection sensor 320 installed inside the sidewall portion 310, and an outer portion 324 of the leak detection sensor 320 installed outside the sidewall portion 310. The sidewall portion 310 may fix and support the leak detection sensor 320 and may be configured to protect the leak detection sensor 320 from external impacts or contamination. Further, the sidewall portion 310 may be configured to maintain airtightness so that the accommodation space 312 of the leak detection sensor 320 does not come into contact with external air. With such a configuration, the leak detection chamber 300 may be maintained in a vacuum state as required.

The controller 600 may control the sensor protection valve VS to open so that the leak detection chamber 300 fluidly communicates with the vacuum pipe PV. When the sensor protection valve VS is controlled to be opened by the controller 600, the leak detection chamber 300 may fluidly communicate with the interior of the vacuum pipe PV through the sensor pipe PS. The air inside the vacuum pipe PV may flow into the interior of the leak detection chamber 300 through the sensor pipe PS. The leak detection sensor 320 may be disposed to be in contact with the air inside the vacuum pipe PV. In this process, the leak detection sensor 320 may acquire composition data of the air inside the vacuum pipe PV.

The inner portion 322 of the leak detection sensor 320 may be located in the accommodation space 312 and be configured to acquire composition data from the air inside the vacuum pipe PV introduced through the sensor pipe PS. For example, the leak detection sensor 320 may be configured to acquire partial pressure data of oxygen in the air inside the vacuum pipe PV. To this end, the leak detection sensor 320 may include a zirconia-based vacuum oxygen sensor.

The outer portion 324 of the leak detection sensor 320 may be disposed so as to be exposed to the outside of the leak detection chamber 300. The outer portion 324 may be configured to allow external air from outside the leak detection chamber 300 to flow into the outer portion 324. If the leak detection sensor 320 is, for example, a zirconia-based vacuum oxygen sensor, the leak detection sensor 320 may calculate the oxygen partial pressure of the air inside the inner portion 322 based on a difference in chemical electromotive force that arises from the external air introduced through the outer portion 324 and the internal air brought into contact with the inner portion 322. That is, the leak detection sensor 320 may compare the external air introduced through the outer portion 324 with the composition data of the internal air detected through the inner portion 322, and may calculate the oxygen partial pressure of the internal air based on that comparison result. Further, if there is no leakage in at least part of the semiconductor equipment, the leak detection sensor 320 may acquire the composition data of the internal air through the inner portion 322 and determine the acquired composition data as reference air composition data (or reference oxygen partial pressure data). However, the method of acquiring reference air composition data is not limited thereto. For example, instead of acquiring composition data of the internal air through the inner portion 322, predetermined reference air composition data may be transmitted to the leak detection sensor 320 through a network or may be stored in the leak detection sensor 320 in advance.

The controller 600 may determine whether the semiconductor equipment is leaking based on the composition data of the air inside the vacuum pipe PV acquired by the leak detection sensor 320. The controller 600 may compare the air composition data of the vacuum pipe PV acquired by the leak detection sensor 320 with predetermined reference air composition data to determine whether leakage is detected in the semiconductor equipment. The controller 600 may compare the oxygen partial pressure data of the air inside the vacuum pipe PV acquired by the leak detection sensor 320 with reference oxygen partial pressure data. For example, if there is no leakage in at least a part of the semiconductor equipment, the oxygen partial pressure of the air inside the vacuum pipe PV or the leak detection chamber 300 may be the same as the reference oxygen partial pressure. However, if the oxygen partial pressure of the internal air is judged to exceed a predetermined threshold, it may be determined that at least a part of the semiconductor equipment is leaking.

The leak detection sensor 320 may acquire composition data of the air inside the vacuum pipe PV and determine whether the semiconductor equipment is leaking based on the acquired composition data. However, the configuration for determining whether the semiconductor equipment is leaking is not limited thereto. For example, the leak detection sensor 320 may acquire composition data of the air inside the vacuum pipe PV, and a separate processor may analyze the composition data acquired by the leak detection sensor 320 to determine whether the semiconductor equipment is leaking.

The sensor protection valve VS may be configured to protect the leak detection sensor 320. The controller 600 may monitor the process progress state in the process chamber and control opening/closing of the sensor pipe PS so as to protect the leak detection sensor 320 from external materials such as process gas. For example, if a process is in progress in the process chamber, the controller 600 may close the sensor protection valve VS. With this configuration, chemically reactive or high-temperature process gas or other contaminants may be prevented from flowing into the leak detection chamber 300 through the sensor pipe PS, thereby preventing physical or chemical damage to the leak detection sensor 320.

The sensor protection valve VS may be disposed on the sensor pipe PS between the leak detection chamber 300 and the vacuum pipe PV in order to protect the leak detection sensor 320 from physical or chemical damage caused by process gas or external air components. Through such a configuration, the sensor protection valve VS may minimize environmental impacts on the leak detection sensor 320 and allow the leak detection sensor 320 to operate in a stable environment.

FIG. 4 illustrates a leak detection system of semiconductor equipment according to some embodiments of the present disclosure.

Referring to FIG. 4, the leak detection system 4 of the semiconductor equipment may include the vacuum pipe PV, the sensor pipe PS, the purge pipe PP, the leak detection chamber 300, the purge chamber 500, the sensor protection valve VS, the purge valve VP, and the controller 600. The purge chamber 500 may include a sidewall portion 510 providing an accommodation space for a purge device 520, and the purge device 520. The controller 600 may be configured to further control operations of the purge valve VP and the purge device 520 included in the purge chamber 500. Hereinafter, overlapping content with FIGS. 1-3 may not be repeated or may be briefly described.

The purge chamber 500 may be in fluid communication with the leak detection chamber 300 through a purge pipe PP disposed on one side of the leak detection chamber 300. The purge pipe PP may be configured to connect the leak detection chamber 300 and the purge chamber 500. The purge pipe PP may serve as a passage for supplying purge gas into the interior of the leak detection chamber 300. A purge valve VP may be disposed on the purge pipe PP. The purge valve VP may be installed on the purge pipe PP and be configured to control an amount of purge gas supplied into the leak detection chamber 300.

The sidewall portion 510 may form an internal space of the purge chamber 500. The sidewall portion 510 may be configured to provide an accommodation space for the purge device 520. The sidewall portion 510 may include an airtight structure so that the flow of purge gas remains stable. One side surface of the sidewall portion 510 may be configured to be in fluid communication with the leak detection chamber 300 through the purge pipe PP. The sidewall portion 510 may include a connection portion with the purge pipe PP for supplying purge gas. The sidewall portion 510 may further include a port to support operation of the purge device 520. The sidewall portion 510 may be configured to maintain airtightness and stability inside the purge chamber 500. Together with the purge device 520, the sidewall portion 510 may deliver purge gas into the leak detection chamber 300 and may optimize the flow and distribution of the purge gas.

The purge device 520 may be configured to supply purge gas into the interior of the leak detection chamber 300. The purge device 520 may stably supply an inert purge gas (e.g., nitrogen gas), thereby protecting the environment surrounding the leak detection sensor 320 and maintaining detection accuracy.

By supplying purge gas to the leak detection chamber 300, the purge device 520 may prevent a highly active gas such as a process gas or halogen gas from physically contacting the leak detection sensor 320. The purge gas may form a stable inert gas environment around the leak detection sensor 320, minimizing damage to the leak detection sensor 320 from particulates or gases generated during a process. For example, because nitrogen gas has chemically inert properties and does not react with the process gas, it may block contact between impurities, that may corrode the material of the leak detection sensor 320 or lower detection accuracy, and the leak detection sensor 320.

The purge valve VP may be configured to control an amount of purge gas supplied into the leak detection chamber 300. The purge valve VP may be configured to adjust flow rate and pressure conditions of the purge gas according to requirements.

The controller 600 may appropriately control operations of each component according to a progress state of a purge operation and the leak detection operation. The controller 600 may control the sensor protection valve VS, the purge valve VP, and so forth so that the environment of the leak detection chamber 300 remains stable and the leak detection sensor 320 collects highly reliable data.

In one embodiment, before controlling the sensor protection valve VS to open, the controller 600 may control the purge valve VP to open. The controller 600 may control the purge valve VP to open so that the purge device 520 supplies purge gas into the leak detection chamber 300. The purge gas filling the interior of the leak detection chamber 300 may provide a pressurized protection function (pressurized protection) against toxic gas from the process chamber 100. That is, if the purge gas fills the leak detection chamber 300 with the sensor protection valve VS kept closed, it may prevent toxic gas generated during the process performed by the process chamber 100 from penetrating into the leak detection chamber 300 through a leakage of the closed sensor protection valve VS, thus avoiding contamination of the leak detection sensor 320. After the purge operation is completed, the controller 600 may close the purge valve VP and open the sensor protection valve VS to prepare for leak detection.

In one embodiment, after controlling the sensor protection valve VS to open, the controller 600 may control the purge valve VP to open. The controller 600 may control the purge valve VP to open to allow the purge device 520 to supply purge gas into the interior of the leak detection chamber 300 while the sensor protection valve VS is opened. In this case, the purge gas may flow through the purge pipe PP, the leak detection chamber 300, and the sensor pipe PS into the vacuum pipe PV. Accordingly, the purge gas may push out the process gas, etc., remaining in the vacuum pipe PV to the outside as well as purge the leak detection chamber 300. After the purge operation is completed, the controller 600 may control the purge valve VP to close so that the internal environment of the leak detection chamber 300 remains stable.

With this configuration, the leak detection system 4 of the semiconductor equipment may protect the leak detection sensor 320 using purge gas and prevent the leak detection sensor 320 from being physically or chemically damaged by process gas or external air components. Thus, the lifespan of the leak detection sensor 320 may be extended and the reliability of detection data may be ensured.

Moreover, with this configuration, the leak detection system 4 of the semiconductor equipment may control operations of each component including a plurality of valves according to the process state on the process chamber, and the state of the leak detection chamber 300 and piping system.

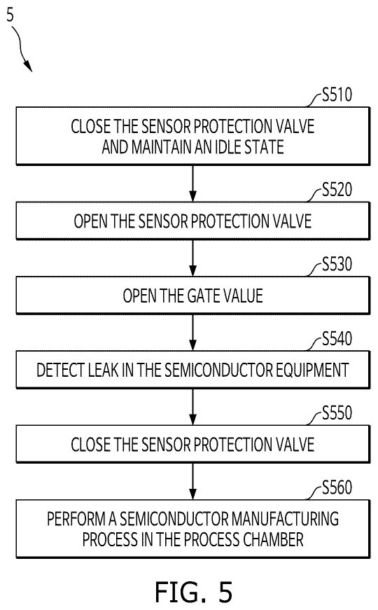

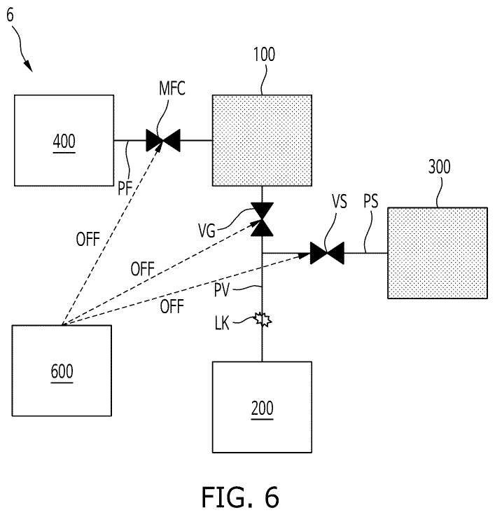

FIG. 5 is a flowchart illustrating a leak detection method of semiconductor equipment according to some embodiments of the present disclosure. FIGS. 6-9 illustrate the leak detection method of the semiconductor equipment of FIG. 5.

In an embodiment, the leak detection method 5 of the semiconductor equipment may be performed by at least one processor (e.g., at least one processor of the controller 600). In another embodiment, at least some of the operations of the leak detection method 5 of the semiconductor equipment may be performed by one or more components included in the leak detection system of the semiconductor equipment (e.g., the process chamber 100, the vacuum pump 200, the leak detection chamber 300, the gas supply chamber 400, etc.). Hereinafter, overlapping content with FIGS. 1-4 may not be repeated or may be briefly described with reference to FIGS. 5-9.

Referring to FIG. 5, in some embodiments, the leak detection method 5 may begin with operation S510, where the at least one processor controls the sensor protection valve to close to block communication between the leak detection chamber including the leak detection sensor and the vacuum pipe, thereby initiating and maintaining an idle state. By performing the operation S510, the leak detection sensor may be isolated and protected from the external environment, and the semiconductor equipment may be set to an initial state for stabilizing the internal environment of the process chamber 100.

Referring to FIGS. 5 and 6, in the operation S510, the controller 600 including at least one processor may control the gate valve VG and the mass flow controller MFC to close. The closed gate valve VG may separate the process chamber 100 from the vacuum pump 200. The closed mass flow controller MFC may block the process chamber 100 from the gas supply chamber 400.

In the operation S510, the process chamber 100 may be maintained in a completely isolated state from external components. The process chamber 100 may be separated from the vacuum pump 200 and the gas supply chamber 400 and may be placed in an idle state. Here, the idle state may be defined as a state in which the process in the process chamber 100 is interrupted or a state in which the semiconductor equipment is stabilized or is prepared for maintenance.

The process chamber 100 may include at least a part of the process gas previously supplied from the gas supply chamber 400 during a prior process. That is, after completion of the prior process, residual gas may remain in the interior of the process chamber 100 if it has not been completely discharged. In a subsequent operation, the residual gas may be analyzed and/or removed to improve process stability and leak detection accuracy.

Referring to FIGS. 5 and 6, in the operation S510, the controller 600 may control the sensor protection valve VS to close. The controller 600 may block fluid communication between the leak detection chamber 300 and the vacuum pipe PV. This may allow the leak detection chamber 300 to remain isolated from the external environment in a sealed state. By performing the operation S510, the leak detection sensor may be protected from external air and the leak detection chamber 300 may be maintained in a vacuum state to improve leak detection accuracy.

If at least a part of the semiconductor equipment is leaking, external air may flow into the semiconductor equipment through the leaked path. If the sensor protection valve VS had been opened in the prior process, leaked external air could have flowed into the leak detection chamber 300 through the vacuum pipe PV and/or the sensor pipe PS. Although the leak detection chamber 300 is cut off from the external environment once the sensor protection valve VS is closed after that process, the already introduced air may remain inside the leak detection chamber 300. The air remaining in the leak detection chamber 300 may be analyzed, and a leak LK that occurred in at least part of the semiconductor equipment may be detected.

In the operation S510, the at least one processor may control the leak detection sensor so that composition data of the air inside the sealed leak detection chamber 300 is acquired. The leak detection sensor may acquire chemical composition or physical property data of the air remaining in the leak detection chamber 300 and determine whether leakage has occurred in the semiconductor equipment based on the acquired data. For example, the at least one processor may analyze the composition data of the air inside the leak detection chamber 300 to detect changes in the concentration of a specific gas component, increases in oxygen partial pressure, and/or whether a specific impurity is detected. Through such analysis, it may be determined whether a minute leak has occurred in the semiconductor equipment, and the location and/or leak path of the minute leak may be estimated. If air composition data different from the reference air composition data is obtained in the leak detection chamber 300 or if air composition data in which the concentration of a specific impurity gas has increased is acquired, it may be inferred that a leak has occurred at a specific location of the semiconductor equipment.

Then, in operation S520, the at least one processor may control the sensor protection valve VS to open. The at least one processor may control the sensor protection valve VS disposed between the vacuum pipe PV and the leak detection chamber 300 including the leak detection sensor so that the leak detection chamber 300 fluidly communicates with the vacuum pipe PV. In FIG. 5, after the operation S520 is performed, operation S530 of opening the gate valve GV is shown to be performed, but embodiments of the present disclosure are not limited thereto. The operations S520 and S530 may in practice be performed simultaneously or the operation S530 may be performed first, followed by the operation S520.

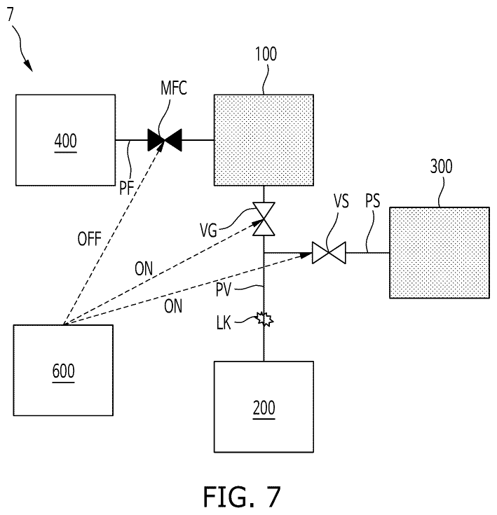

Referring to FIGS. 5 and 7, when the sensor protection valve VS is opened in the operation S520, the leak detection chamber 300 may be placed in fluid communication with the vacuum pipe PV through the sensor pipe PS. In this state, the internal air of the vacuum pipe PV may flow into the leak detection chamber 300 through the sensor pipe PS. The controller 600 may control the leak detection sensor included in the leak detection chamber 300 to sample the introduced air and acquire its composition data. The leak detection sensor may acquire the chemical composition (e.g., oxygen partial pressure, impurity concentration, etc.) or physical composition (e.g., pressure, temperature, etc.) of at least one from among the vacuum pipe PV and the sensor pipe PS. The controller 600 may determine whether the semiconductor equipment is leaking based on the acquired composition data.

In one embodiment, in the operation S520, the controller 600 may receive oxygen partial pressure data acquired by the leak detection sensor about an inside of the vacuum pipe. The controller 600 may compare the received oxygen partial pressure data with predetermined reference oxygen partial pressure data to determine whether leakage is detected in the semiconductor equipment. If the controller 600 detects an abnormal increase or change in the oxygen partial pressure, it may be inferred that external air has entered the interior of the semiconductor equipment due to a leak LK. The leak detection sensor may include a zirconia-based vacuum oxygen sensor to acquire such composition data.

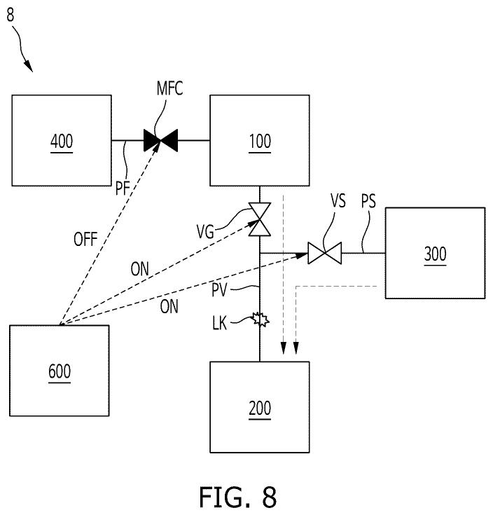

Referring to FIGS. 5 and 8, in the operation S520, the at least one processor may maintain the vacuum pump 200 in an operational state to discharge the residual air in the leak detection chamber 300 to the outside. Through this configuration, errors in leak detection that may result from residual air in the leak detection chamber 300 are minimized, and the inside of the leak detection chamber 300 may be converted to a vacuum state or exchanged with new air.

Next, in the operation S530, the at least one processor may control the gate valve VG to open (turn on). When the gate valve VG installed on the vacuum pipe PV is opened, the process chamber 100 and the vacuum pump 200 may be placed in fluid communication. By opening the gate valve VG, the at least one processor may place the process chamber 100 and the vacuum pump 200 in fluid communication with each other through the vacuum pipe PV.

During execution of the operations S520 and S530, the at least one processor may operate the vacuum pump 200. Alternatively, the at least one processor may continuously operate the vacuum pump 200 during execution of the leak detection method 5. By controlling the opening/closing of at least one from among the sensor protection valve SV and the gate valve VG while the vacuum pump 200 is operating, the at least one processor may regulate the effect of the vacuum action by the vacuum pump 200 on the vacuum pipe PV and the leak detection chamber 300 connected thereto. Referring to FIGS. 5 and 8, while the gate valve GV is open, the at least one processor may operate the vacuum pump 200 to discharge residual gas or unnecessary air inside the process chamber 100 to the outside. Accordingly, the process chamber 100 may be maintained in a vacuum state suitable for a high-vacuum process or maintained at a specific pressure level. The operation S530 may correspond to an operation of preparing so that the subsequent flow of process gas into the process chamber 100 may be optimized or so that the leak detection system stably operates under a vacuum state.

Next, in operation S540, the at least one processor may detect whether the semiconductor equipment is leaking using the leak detection sensor. This may allow the at least one processor to evaluate the stability of the vacuum environment of the semiconductor equipment and to check in real time whether the process chamber 100 and/or the vacuum pipe PV is leaking.

Referring to FIGS. 7 and 8, in the operation S540, while both the gate valve VG and the sensor protection valve VS are open, the leak detection chamber 300 may be in fluid communication with the process chamber 100 and the vacuum pump 200 through the sensor pipe PS and the vacuum pipe PV. This communication state may maintain the vacuum environment inside the semiconductor equipment and deliver the internal air of the vacuum pipe PV and the process chamber 100 to the leak detection chamber 300 so that the leak detection sensor acquires the air composition and determines whether leakage is present.

Referring to FIG. 8, while the vacuum pump 200 is in operation, the leak detection sensor may detect the composition of the air flowing into the leak detection chamber 300 and determine, based thereon, whether leakage has occurred inside the semiconductor equipment. The vacuum pump 200 may continuously discharge internal air of the process chamber 100 and the vacuum pipe PV to the outside, maintaining the leak detection chamber 300 in a vacuum state and thereby providing a reference state for leak detection.

If a leak is present inside the semiconductor equipment, even while the vacuum pump 200 is operating, external air or impurity gas may flow into the interior through a leak path. The introduced air may be transferred to the leak detection chamber 300 and detected by the leak detection sensor. For example, if the oxygen concentration introduced from the external air is higher than a predetermined reference value compared to the vacuum state, or if a specific impurity gas is detected, a leak may be inferred. That is, in operation S550, an environment may be formed in which changes in air composition or concentration resulting from external air inflow may be detected inside the semiconductor equipment.

Next, in the operation S550, the at least one processor may control the sensor protection valve VS to close. The operation S550 may include isolating the leak detection sensor and the leak detection chamber 300 from the external environment and from the process pipe PV before executing the process in the process chamber 100, after leak detection is completed.

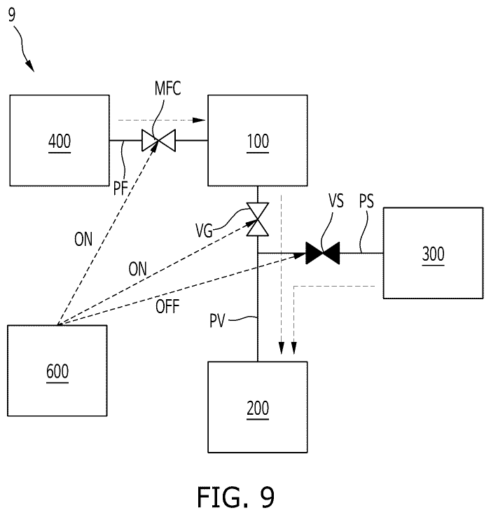

Referring to FIG. 9, with the sensor protection valve VS closed, fluid communication between the leak detection chamber 300 and the vacuum pipe PV may be blocked. Thus, the leak detection chamber 300 may be shielded, and during a process in the process chamber 100, high temperatures, chemically reactive process gas, or external contaminants that may occur in the process chamber 100 may be prevented from reaching the leak detection sensor, thereby safely protecting the leak detection sensor.

The at least one processor may control the sensor protection valve VS and switch the leak detection chamber 300 to a stable idle state. After the sensor protection valve VS is closed, the leak detection chamber 300 and the leak detection sensor may remain isolated from the outside and may prepare for the next leak detection process.

In operation S560, the at least one processor may perform a semiconductor manufacturing process in the process chamber 100. In the operation S560, the semiconductor manufacturing process may begin, and the internal state of the process chamber 100 may be controlled so as to satisfy predetermined process initiation conditions (e.g., temperature, pressure, gas composition, etc.).

Referring to FIGS. 5 and 9, in the operation S560, the at least one processor may control the MFC installed on the gas pipe PF to open. The gas pipe PF may be configured to communicate the gas supply chamber 400 with the process chamber 100 so that process gas may be provided into the process chamber 100. The at least one processor may control the MFC to regulate the flow rate and concentration of the process gas supplied into the process chamber 100. A semiconductor manufacturing process may be performed in the process chamber 100 using the supplied process gas.

Referring to FIGS. 5 and 9, in the operation S560, the at least one processor may control the gate valve VG to open. The gate valve VG may connect the vacuum pump 200 and the process chamber 100. With the vacuum pump 200 operating, the at least one processor may discharge exhaust gas or unnecessary byproducts generated during the process inside the process chamber 100 to the outside. After the operation S560 of the leak detection method 5, the operation S510 may be performed again, and the operations S510-S560 may be repeated multiple times.

If occurrence of leakage in the semiconductor equipment is inferred or detected (e.g., by the controller 600) during any of the operations S520-S540, the controller 600 may send a warning signal to an external device connected to the semiconductor equipment (e.g., a display device, user terminal device, etc.) or may stop the semiconductor equipment process.

According to the above-described configuration, before or after execution of the process by the process chamber 100, the controller 600 may control the sensor protection valve VS to be opened while the vacuum pump 200 is operated, so that the leak detection sensor is controlled to communicate with the vacuum pipe PV. In a state where the leak detection chamber 300 and the semiconductor equipment are in fluid communication, the controller 600 may control the leak detection sensor to acquire composition data of the air inside the vacuum pipe PV. Further, the controller 600 may determine whether leakage occurs in the semiconductor equipment based on the acquired composition data.

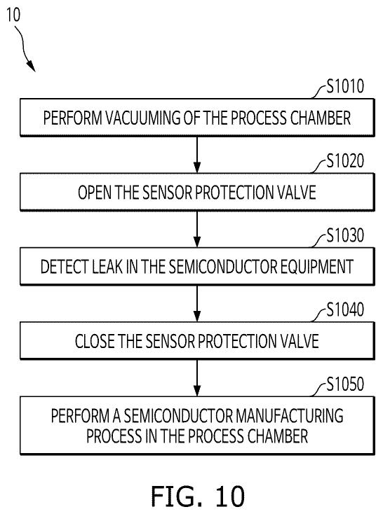

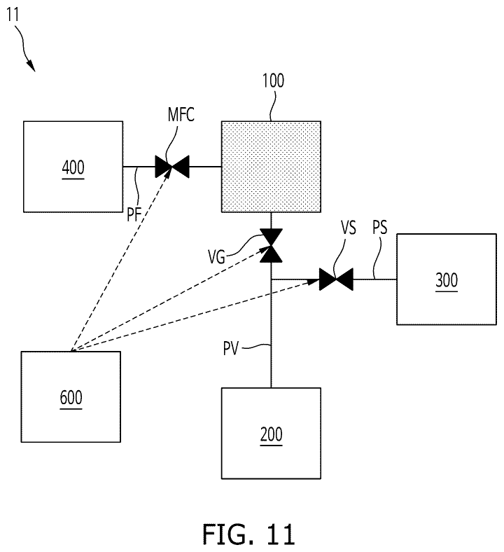

FIG. 10 is a flowchart illustrating a leak detection method of semiconductor equipment according to some embodiments of the present disclosure. FIG. 11 illustrates the leak detection method of the semiconductor equipment of FIG. 10.

The leak detection method 10 of the semiconductor equipment may be performed by at least one processor (e.g., the at least one processor of the controller 600). The leak detection method 10 may include operation S1010 of vacuuming the process chamber, operation S1020 of opening the sensor protection valve, operation S1030 of detecting whether the semiconductor equipment is leaking, operation S1040 of closing the sensor protection valve, and operation S1050 of performing a process in the process chamber. The operation S1020 of FIG. 10 may correspond to the operations S520 and S530 of FIG. 5. The operations S1030, S1040, and S1050 of FIG. 10 may respectively correspond to the operations S540, S550, and S560 of FIG. 5. Hereinafter, overlapping content with FIGS. 1-9 may not be repeated or may be briefly described with reference to FIGS. 10 and 11.

Referring to FIGS. 10 and 11, in the operation S1010, the at least one processor may perform vacuuming of the process chamber. For example, the at least one processor of the controller 600 may maintain the operation of the vacuum pump 200 while the gate valve VG is open, thereby vacuuming the process chamber 100. Also, the at least one processor may maintain the sensor protection valve VS in a closed state, thereby blocking fluid communication between the leak detection chamber 300 and the vacuum pipe PV. Operation S1010 may be an operation in which the leak detection sensor is isolated from the external environment and may remain stabilized under a vacuum state.

Next, in the operation S1020, the at least one processor may control the sensor protection valve VS to open. Under a state in which the process chamber 100 and the leak detection sensor accommodated in the leak detection chamber 300 maintain vacuum, the at least one processor may control the sensor protection valve VS to open, thereby establishing fluid communication between the leak detection chamber 300 and the vacuum pipe PV. When the sensor protection valve VS is opened in the operation S1020, the leak detection sensor may subsequently sample air introduced from the vacuum pipe PV and/or the process chamber 100 and acquire composition data of that air. Further, by comparing the acquired composition data with reference air composition data, the at least one processor may determine whether the semiconductor equipment is leaking.

The operations S1010-S1050 of the leak detection method 10 illustrated in FIG. 10 may be repeatedly performed. That is, after the process of the process chamber 100 is executed in the operation S1050, the process chamber 100 may be vacuumed again in the operation S1010, and the subsequent operations may be performed.

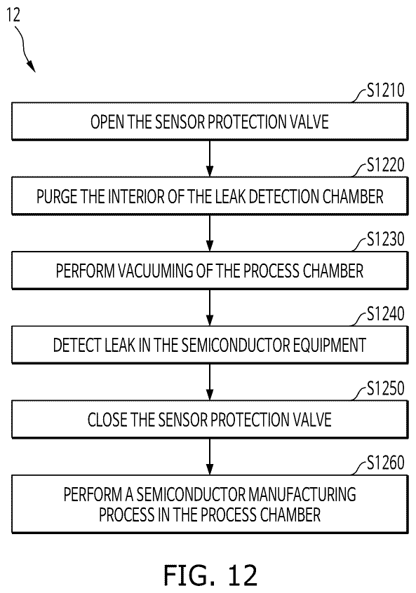

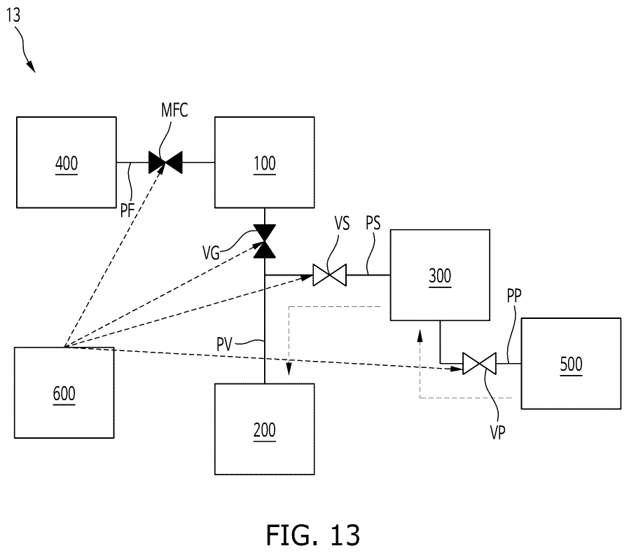

FIG. 12 is a flowchart illustrating a leak detection method of semiconductor equipment according to some embodiments of the present disclosure. FIG. 13 illustrates the leak detection method of the semiconductor equipment of FIG. 12.

The leak detection method 12 of the semiconductor equipment may be performed by at one processor (e.g., the at least one processor of the controller 600). The leak detection method 12 may include operation S1210 of opening the sensor protection valve, operation S1220 of purging the interior of the leak detection chamber, operation S1230 of vacuuming the process chamber, operation S1240 of detecting whether the semiconductor equipment is leaking, operation S1250 of closing the sensor protection valve, and operation S1260 of performing a process in the process chamber. The operation S1210 of FIG. 12 may correspond to the operations S510 and S520 of FIG. 5. The operation S1230 of FIG. 12 may correspond to the operations S530 and S540 of FIG. 5. The operations S1240, S1250, and S1260 of FIG. 12 may respectively correspond to the operations S540, S550, and S560 of FIG. 5. Hereinafter, overlapping content with FIGS. 1-11 may not be repeated or may be briefly described with reference to FIGS. 12 and 13.

Referring to FIG. 13, the leak detection system 13 of the semiconductor equipment may include a purge chamber 500 including a purge device (e.g., a purge gas supplier) configured to supply purge gas into the leak detection chamber 300, a purge pipe PP configured to place the interior of the leak detection chamber 300 in fluid communication with the purge chamber 500, and a purge valve VP installed on the purge pipe PP and configured to control an amount of purge gas supplied into the leak detection chamber 300.

Referring to FIGS. 12 and 13, in the operation S1210, the at least one processor may open the sensor protection valve VS. With the sensor protection valve VS opened, the leak detection chamber 300 may be in fluid communication with the vacuum pipe PV and the sensor pipe PS. This communication state may be a preparation state for purging the leak detection chamber 300 in the next operation S1220.

Then, in the operation S1220, the at least one processor may open the purge valve VP. With the purge valve VP opened, the purge chamber 500 may be in fluid communication with the leak detection chamber 300 through the purge pipe PP. The at least one processor may operate the purge device included in the purge chamber 500 to supply purge gas (e.g., nitrogen gas) to the leak detection chamber 300.

The purge gas supplied to the leak detection chamber 300 may push out process gas, external air, and other impurities remaining inside the leak detection chamber 300. The purge gas may prevent the leak detection sensor from being physically and/or chemically damaged by a highly reactive process gas (e.g., halogen gas). Through this, the accuracy of the leak detection operation by the leak detection sensor may be improved.

With both the sensor protection valve VS and the purge valve VP open, as purge gas is supplied to the leak detection chamber 300, the purge gas may flow not only into the leak detection chamber 300 but also into the sensor pipe PS and the vacuum pipe PV. In the operation S1220, by keeping the vacuum pump 200 in operation, the at least one processor may induce residual gas and impurities displaced into the vacuum pipe PV by the purge gas to be discharged to the outside.

Through this configuration, it is possible to keep the leak detection chamber 300 and its connecting pipes in an inert state and to create an environment in which the leak detection sensor may acquire accurate and reliable composition data.

In the operation S1220, when the supply of purge gas is completed or the purge operation is completed, the at least one processor may close the purge valve VP. By performing the above-described operations, the leak detection chamber 300 may be switched to a stable state in which impurities are removed. The at least one processor may then open the sensor protection valve VS or keep it open and proceed with subsequent operations.

The operations S1210-S1260 of the leak detection method 12 illustrated in FIG. 12 may be repeated. That is, after the process of the process chamber 100 is executed in the operation S1260, the operation S1210 of opening the sensor protection valve SV may be performed again, and subsequent operations may be performed.

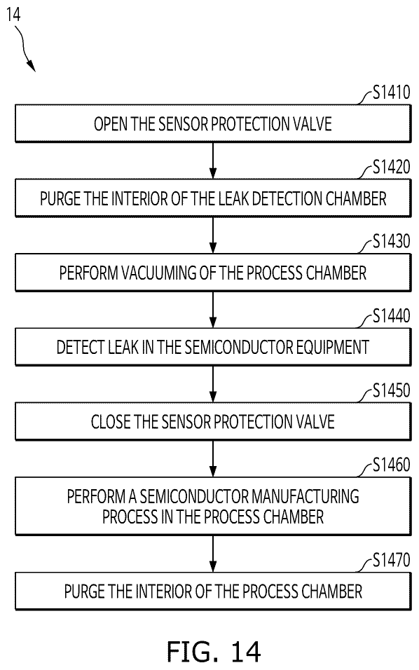

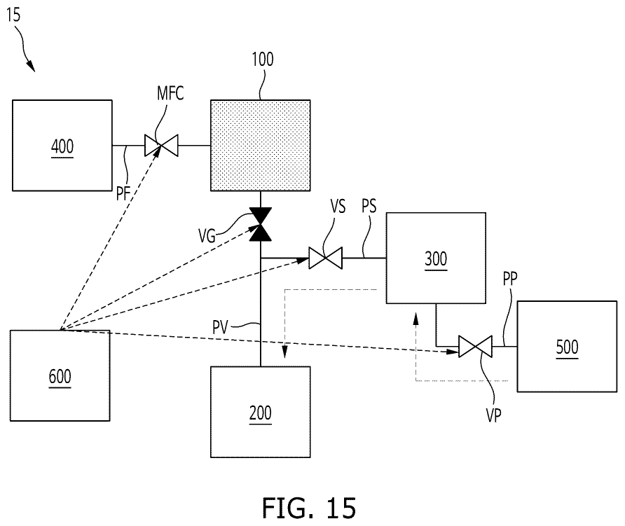

FIG. 14 is a flowchart illustrating a leak detection method of semiconductor equipment according to some embodiments of the present disclosure. FIG. 15 illustrates the leak detection method of the semiconductor equipment of FIG. 14.

The leak detection method 14 of the semiconductor equipment may be performed by at least one processor (e.g., the at least one processor of the controller 600). The leak detection method 14 may include operation S1410 of opening the sensor protection valve, operation S1420 of purging the interior of the leak detection chamber, operation S1430 of vacuuming the process chamber, operation S1440 of detecting whether the semiconductor equipment is leaking, operation S1450 of closing the sensor protection valve, operation S1460 of performing a process in the process chamber, and operation S1470 of purging the interior of the process chamber. The operations S1410, S1420, S1430, S1440, S1450, and S1460 of FIG. 14 may respectively correspond to the operations S1210, S1220, S1230, S1240, S1250, and S1260 of FIG. 12. Hereinafter, overlapping content with FIGS. 1-13 may not be repeated or may be briefly described with reference to FIGS. 14 and 15.

In the operation S1460, the at least one processor may open the purge valve VP while a process is being performed in the process chamber 100. The at least one processor may control the purge device included in the purge chamber 500 connected to one side of the leak detection chamber 300 so that the purge device supplies purge gas into the leak detection chamber 300. Once the supply of purge gas is completed, the at least one processor may close the purge valve VP and open the sensor protection valve VS.

In the operation S1470, the at least one processor may supply purge gas into the process chamber 100 through the opened MFC. The gas supply chamber 400 may provide not only the process gas required for the process through the gas pipe PF but also purge gas needed to purge the interior of the process chamber 100. The purge gas may remove residual gas, byproducts, and/or impurities generated during the process, thereby initializing the process chamber 100 in an inert state. After completing the purge operation, the at least one processor may close the MFC to stop gas supply.

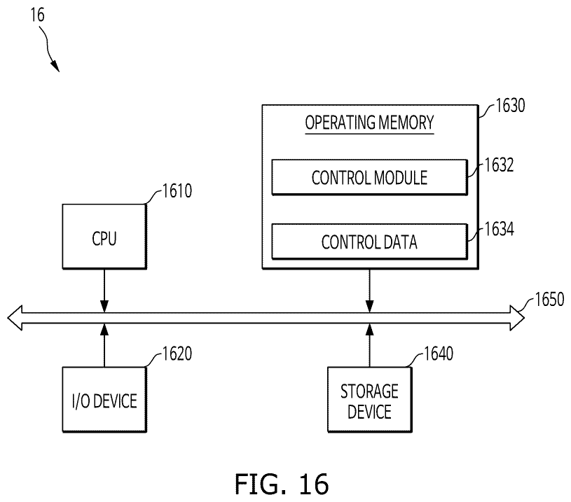

FIG. 16 is a block diagram illustrating a configuration of a computing device implementing the controller according to some embodiments of the present disclosure.

FIG. 16 is a block diagram illustrating a computing device 16 in which a controller (e.g., the controller 600) according to embodiments of the present disclosure may be implemented. The computing device 15 may include a central processing unit (CPU) 1610 (or processor), an operating memory 1630, an I/O device 1620, and a storage device 1640 (e.g., a storage).

The CPU 1610 may execute software (e.g., an application program including a program for executing the leak detection method of semiconductor equipment, an operating system, device drivers) to be performed in the computing device 16. The CPU 1610 may process data or output control signals according to a program stored in the operating memory 1630.

The operating memory 1630 may be a volatile memory such as static random access memory (SRAM) or dynamic random access memory (DRAM), or a nonvolatile memory such as parameter random access memory (PRAM), magnetoresistive random access memory (MRAM), resistive random access memory (ReRAM), ferroelectric random access memory (FRAM), or NOR flash memory.

The operating memory 1630 may store a control module 1632 that includes program code for executing the leak detection method(s) of semiconductor equipment. For example, the program code, when executed by the computing device 16, may be configured to control the computing device 16 to perform the leak detection methods 5, 10, 12, and/or 14. The control module 1632 may refer to data such as the internal state of the leak detection chamber (e.g., internal pressure, gas composition, temperature changes), the internal process state of the process chamber (e.g., flow rate, pressure, temperature of process gas), and a progress state of a purge operation through the purge chamber.

The I/O device 1620 may receive input from a user interface and output data. For example, I/O device 1620 may be configured to include an input interface for setting the leak detection cycle of the semiconductor equipment, an input interface through which the user can set process conditions (e.g., flow rate and pressure of process gas), and an output interface for outputting internal state data of the leak detection chamber 300 or the vacuum pipe PV.

The storage device 1640 may be provided as a storage medium of the computing device 16. The storage device 1640 may store data collected during the leak detection operation (e.g., internal pressure of the vacuum pipe, gas composition data, temperature changes, etc.). The storage device 1640 may be provided as a memory card (MMC, eMMC, SD, MicroSD, etc.) or a hard disk drive (HDD). The storage device 1640 may include a NAND-type flash memory that has a large storage capacity. Alternatively, the storage device 1640 may include next-generation nonvolatile memory such as PRAM, MRAM, ReRAM, FRAM, or NOR flash memory.

According to some embodiments of the present disclosure, a method performed by a controller, including at least one processor, may be provided and include: opening a sensor protection valve that is between a vacuum pipe and a leak detection chamber so that the leak detection chamber fluidly communicates with the vacuum pipe, the leak detection chamber including a leak detection sensor; opening a gate valve on the vacuum pipe so that a process chamber and a vacuum pump fluidly communicate with each other; acquiring, by the leak detection sensor, composition data of air inside at least one from among the process chamber and the vacuum pipe; determining, based on the composition data, whether semiconductor equipment is leaking, the semiconductor equipment including the process chamber and the vacuum pipe; closing the sensor protection valve so as to block fluid communication between the vacuum pipe and the leak detection chamber; and controlling a mass flow controller (MFC) on a gas pipe so that process gas is supplied to the process chamber by a gas supply chamber, the gas pipe configured to place the gas supply chamber in fluid communication with the process chamber.

According to some embodiments of the present disclosure, the acquiring the composition data including acquiring, by the leak detection sensor, oxygen partial pressure data of the air inside the vacuum pipe, and wherein the determining whether the semiconductor equipment is leaking includes comparing the oxygen partial pressure data and predetermined reference oxygen partial pressure data to determine whether the semiconductor equipment is leaking.

According to some embodiments of the present disclosure, the leak detection sensor includes a zirconia-based vacuum oxygen sensor.

According to some embodiments of the present disclosure, the method further includes: opening a purge valve so that a purge gas supplier connected to the leak detection chamber supplies a purge gas into the leak detection chamber; and after completing supply of the purge gas, closing the purge valve and opening the sensor protection valve.

According to some embodiments of the present disclosure, the method further includes: opening the sensor protection valve before a purge gas supplier connected to the leak detection chamber supplies a purge gas into the leak detection chamber; and opening a purge valve so that the purge gas supplier supplies the purge gas into the leak detection chamber.

According to some embodiments of the present disclosure, the method further includes: opening, before or after a process is executed in the process chamber, a purge valve so that a purge gas supplier connected to the leak detection chamber supplies a purge gas into the leak detection chamber; and after completing supply of the purge gas, closing the purge valve and opening the sensor protection valve.

Although non-limiting example embodiments of the present disclosure have been described above with reference to the accompanying drawings, the present disclosure is not limited thereto, and it will be apparent to those skilled in the art that various modifications and variations are possible within the spirit and scope of the present disclosure.

What is claimed is:

1. A system comprising:
a process chamber;
a vacuum pump configured to maintain the process chamber in a vacuum state;
a vacuum pipe connecting an interior of the process chamber and the vacuum pump;
a leak detection chamber connected to the vacuum pipe, the leak detection chamber comprising a leak detection sensor configured to detect whether a leakage occurs in the system;
a sensor protection valve between the vacuum pipe and the leak detection chamber, the sensor protection valve configured to control whether air inside the vacuum pipe contacts the leak detection sensor; and
a controller comprising at least one processor, the controller configured to control operations of the vacuum pump and the sensor protection valve according to a process progress state of the process chamber,
wherein the controller is further configured to operate the vacuum pump before or after execution of a process by the process chamber, and control the sensor protection valve to open so that the leak detection chamber fluidly communicates with the vacuum pipe,
wherein, in a state where the leak detection chamber and the process chamber are in fluid communication, the leak detection sensor is configured to acquire composition data of air inside the vacuum pipe, and
wherein the controller is further configured to determine whether the system is leaking based on the composition data.

2. The system of claim 1, wherein the leak detection sensor is configured to acquire oxygen partial pressure data of the air inside the vacuum pipe, and
wherein the controller is further configured to compare the oxygen partial pressure data and predetermined reference oxygen partial pressure data to determine whether the system is leaking.

3. The system of claim 2, wherein the leak detection sensor comprises a zirconia-based vacuum oxygen sensor.

4. The system of claim 1, further comprising a gate valve on the vacuum pipe, the gate valve configured to control the fluid communication between the process chamber and the vacuum pump,
wherein the controller is further configured to:
control both the gate valve and the sensor protection valve to open; and
determine whether the system leaks based on the composition data acquired by the leak detection sensor, while the vacuum pump is vacuuming the process chamber.

5. The system of claim 1, further comprising:
a purge chamber connected to the leak detection chamber, the purge chamber comprising a purge gas supplier configured to supply a purge gas into the leak detection chamber;
a purge pipe; and
a purge valve on the purge pipe, the purge valve configured to place the leak detection chamber and the purge chamber in fluid communication, the purge valve further configured to control an amount of the purge gas supplied into the leak detection chamber,
wherein the controller is further configured to control an operation of the purge valve and the purge gas supplier.

6. The system of claim 5, wherein the controller is further configured to:
control the purge valve to open to allow the purge gas supplier to supply the purge gas into the leak detection chamber before the sensor protection valve is opened; and
after the supply of the purge gas is completed, control the purge valve to close and the sensor protection valve to open.

7. The system of claim 5, wherein the controller is further configured to:
after controlling the sensor protection valve to open, control the purge valve to open to allow the purge gas supplier to supply the purge gas into the leak detection chamber; and
after the supply of the purge gas is completed, control the purge valve to close.

8. The system of claim 1, further comprising:
a gas supply chamber configured to supply a process gas into the process chamber;
a process gas pipe configured to place the process chamber and the gas supply chamber in fluid communication; and
a mass flow controller (MFC) on the process gas pipe, the MFC configured to control a flow rate of the process gas supplied into the process chamber,
wherein the controller is further configured to control the MFC so that the process gas is supplied to the process chamber through the process gas pipe.

9. The system of claim 8, further comprising a gate valve on the vacuum pipe, the gate valve configured to control whether the process chamber and the vacuum pump are in fluid communication,
wherein the controller is further configured to control, before execution of the process by the process chamber, the gate valve to maintain communication between the process chamber and the vacuum pump.

10. The system of claim 9, wherein the controller is further configured to, while the process is executed by the process chamber, control the sensor protection valve to close so that the leak detection sensor does not contact the process gas.

11. The system of claim 1, wherein the controller is further configured to, before the process is executed by the process chamber:
control the sensor protection valve to open so that the leak detection chamber and the vacuum pipe are in fluid communication;
control the leak detection sensor to acquire the composition data of air inside the vacuum pipe; and
determine whether the system is leaking based on the composition data.

12. The system of claim 1, further comprising:
a purge chamber connected to the leak detection chamber, the purge chamber comprising a purge gas supplier configured to supply a purge gas into the leak detection chamber;
a purge pipe; and
a purge valve on the purge pipe, the purge valve configured to place the leak detection chamber and the purge chamber in fluid communication and control an amount of the purge gas supplied into the leak detection chamber,
wherein the controller is further configured to, before the process is executed by the process chamber, open both the sensor protection valve and the purge valve so that the purge gas supplier supplies the purge gas into the leak detection chamber and the vacuum pipe.

13. The system of claim 1, further comprising:
a purge chamber connected to the leak detection chamber, the purge chamber comprising a purge gas supplier configured to supply a purge gas into the leak detection chamber;
a purge pipe; and
a purge valve on the purge pipe, the purge valve configured to place the leak detection chamber and the purge chamber in fluid communication and control an amount of the purge gas supplied into the leak detection chamber,
wherein the controller is further configured to control the purge valve to open while the sensor protection valve is closed so that the purge gas supplier supplies the purge gas into the leak detection chamber.

14. A controller comprising:
at least one processor configured to:
control a sensor protection valve, that is between a vacuum pipe and a leak detection chamber, to open so that the leak detection chamber fluidly communicates with the vacuum pipe, the leak detection chamber comprising a leak detection sensor;
control a gate valve on the vacuum pipe to open so that a process chamber and a vacuum pump fluidly communicate with each other;
determine, based on composition data of air inside at least one from among the process chamber and the vacuum pipe acquired by the leak detection sensor, whether semiconductor equipment is leaking, the semiconductor equipment including the process chamber and the vacuum pipe;
control the sensor protection valve to close so as to block fluid communication between the vacuum pipe and the leak detection chamber; and
control a mass flow controller (MFC) on a gas pipe so that process gas is supplied to the process chamber by a gas supply chamber, the gas pipe configured to place the gas supply chamber in fluid communication with the process chamber.

15. The controller of claim 14, wherein the leak detection sensor is configured to acquire oxygen partial pressure data of the air inside the vacuum pipe, and
wherein the at least one processor is further configured to compare the oxygen partial pressure data and predetermined reference oxygen partial pressure data to determine whether the semiconductor equipment is leaking.

16. The controller of claim 15, wherein the leak detection sensor comprises a zirconia-based vacuum oxygen sensor.

17. The controller of claim 14, wherein the at least one processor is further configured to:
control a purge valve to open so that a purge gas supplier connected to the leak detection chamber supplies a purge gas into the leak detection chamber; and
after completing supply of the purge gas, control the purge valve to close and the sensor protection valve to open.

18. The controller of claim 14, wherein the at least one processor is further configured to:
control the sensor protection valve to open before a purge gas supplier connected to the leak detection chamber supplies a purge gas into the leak detection chamber; and
control a purge valve to open so that the purge gas supplier supplies the purge gas into the leak detection chamber.

19. The controller of claim 14, wherein the at least one processor is further configured to:
control, before or after a process is executed in the process chamber, a purge valve to open so that a purge gas supplier connected to the leak detection chamber supplies a purge gas into the leak detection chamber; and
after completing supply of the purge gas, control the purge valve to close and the sensor protection valve to open.

20. A system comprising:
a process chamber;
a vacuum pump configured to maintain the process chamber in a vacuum state;
a vacuum pipe connecting an interior of the process chamber and the vacuum pump;
a gate valve on the vacuum pipe, the gate valve configured to control whether the process chamber and the vacuum pump fluidly communicate with each other;
a leak detection chamber connected to the vacuum pipe, the leak detection chamber comprising a leak detection sensor configured to detect whether a leakage occurs in the system;
a sensor protection valve between the vacuum pipe and the leak detection chamber, the sensor protection valve configured to control whether air inside the vacuum pipe contacts the leak detection sensor;
a purge chamber connected to the leak detection chamber, the purge chamber comprising a purge gas supplier configured to supply a purge gas into the leak detection chamber;
a purge pipe;
a purge valve on the purge pipe, the purge valve configured to place the leak detection chamber and the purge chamber in fluid communication and control an amount of the purge gas supplied into the leak detection chamber; and
a controller comprising at least one processor, the controller configured to control an operation of at least one from among the gate valve, the sensor protection valve, the purge valve, the vacuum pump, the leak detection sensor, and the purge gas supplier according to a process progress state of the process chamber,
wherein the controller is further configured to operate the vacuum pump before or after execution of a process by the process chamber, and open the sensor protection valve so that the leak detection chamber fluidly communicates with the process chamber,
wherein the controller is further configured to in a state where the leak detection chamber and the process chamber are in fluid communication, control the leak detection sensor to acquire composition data of air inside the vacuum pipe, and
wherein the controller is further configured to determine whether the system is leaking based on the composition data.
